(19) United States
(12) Patent Application Publication
(10) Pub. No.: US 2009/0147459 A1
(43) Pub. Date: Jun. 11, 2009

(54) Modular Power Supply for Computer Servers

(75) Inventors: Hai N. Nguyen, Spring, TX (US); Mohamed Amin Bemat, Cypress, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: HEWLETT-PACKARD DEVELOPMENT COMPANY, L.P., Houston, TX (US)

(21) Appl. No.: 11/951,311

(22) Filed: Dec. 5, 2007

(51) Int. Cl. H05K 5/02; H01S 4/00; A47B 81/00

(52) U.S. Cl. 361/679.31; 29/592.1; 312/223.2

(57) ABSTRACT

A system, in certain embodiments, may include a server power supply having a modular chassis having dimensions standardized across a plurality of different servers. The dimensions may be configured to fit the modular chassis uniformly within receptacles of the plurality of different servers. A method of manufacture, in certain embodiments, may include providing a server power supply having a modular chassis with dimensions standardized across a plurality of different servers. Again, the dimensions may be configured to fit the modular chassis uniformly within receptacles of the plurality of different servers.

### BACKGROUND

This section is intended to introduce the reader to various aspects of art, which may be related to various aspects of the present invention that are described or claimed below. This discussion is believed to be helpful in providing the reader with background information to facilitate a better understanding of the various aspects of the present invention. Accordingly, it should be understood that these statements are to be read in this light, and not as admissions of prior art.

Computer servers are used by a wide array of users in various configurations. For example, such servers or server systems may be used in telecommunications, financial, commercial, retail, and aviation industries. Server systems often comprise multiple servers housed in an enclosure and/or in standard rack mount. Such servers may be referred to as blade servers, rack-mount servers, or a server cluster depending on the configuration and type of housing. As processing needs and computing performance have increased, servers have become more powerful while being offered in multiple configurations, sizes, and form factors. Thus, server enclosures and rack mount systems are capable of enclosing an increasing number of these different servers, and users may house or use several types of servers, enclosures, and/or racks. In some cases each server may require an individual power supply housed in the chassis of the server or in an enclosure or rack. In other cases, servers may share a power supply or require multiple power supplies. The different configurations, sizes, and form factors of the different servers require different power supplies for each server, adding cost, complexity, and increased inventory management. Additionally, in some instances the input power to the enclosure, rack, cluster, or individual server may very depending on the country or location of the server. Further, new servers that use newer processors, memory, or other components may have different power requirements than older servers and thus require new or redesigned power supplies.

### BRIEF DESCRIPTION OF THE DRAWINGS

FIG. 1 is a perspective view illustrating a rack mount system having a plurality of servers with modular power supplies in accordance with an embodiment of the present invention;

FIG. 2 is a perspective view of a blade server enclosure having modular power supplies with a standard form factor, connectors, and other features, in accordance with an embodiment of the present invention;

FIG. 3 is a rear perspective view of a modular power supply in accordance with an embodiment of the present invention;

FIG. 4 is a front view of the modular power supply of FIG. 1 in accordance with an embodiment of the present invention;

FIG. 5 is a top view of the modular power supply of FIG. 1 in accordance with an embodiment of the present invention;

FIG. 6 is a bottom view of a modular power supply of FIG. 1 in accordance with an embodiment of the present invention; and

FIGS. 7A and 7B are top and bottom views respectively of a card-edge connector of a modular power supply in accordance with an embodiment of the present invention.

### DETAILED DESCRIPTION OF SPECIFIC EMBODIMENTS

One or more exemplary embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As discussed in greater detail below, one or more embodiments of the present invention provide a modular power supply having a standard form factor for use in multiple server types, server families, and configurations. The standard form factor may include a standard height and width, and also may include a standard length. Furthermore, the modular power supply may include a standard power output connector, standard position for the connector, and so forth. For example, such a power supply may be used in rack mount servers, blade servers, and/or server clusters, or across a family of servers. As a result, the number and variations in the power supplies across different servers is drastically reduced to improve uniformity, reduce costs, increase compatibilities, and so forth.

In one embodiment, a modular power supply may be configured to slidingly mount in a receptacle in a server chassis. The power supply may include an input connector, a handle, a fan, an output connector, and various other components to ensure easy connection, installation, and removal. Advantageously, the modular power supply and a corresponding standardized receptacle in a server enables easy use, replacement, and design of the modular power supply. For example, standardization of the power supply may result in easier servicing, lower costs of manufacture, and reuse and interchangeability of the power supply across different servers. Further, the specification or design of the power supply need not be changed if a new server or processor or other component is released, as the power supply can be adapted or used in parallel to meet the power needs of the new server or components. Additionally, inventory control and management is streamlined, as only one type of power supply need be stored as spare parts for multiple servers, and demand for power supplies can be balanced across multiple servers. Thus, the power supply may be treated as other interchangeable components of a server, such as a hard disk drive or a PCI expansion card.

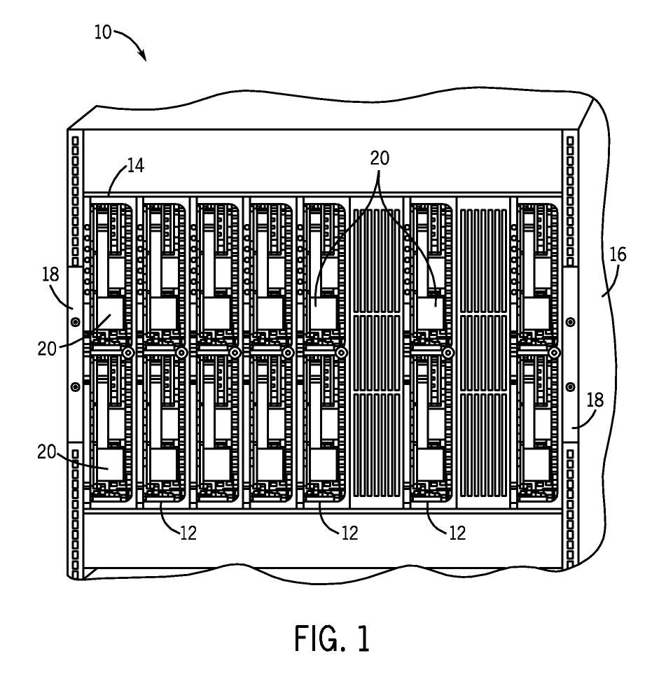

Turing now to the figures, an exemplary rack mount system 10 is illustrated in FIG. 1. In the exemplary embodiment, the rack mount system 10 includes a number of computer servers 12 disposed within a chassis or enclosure 14. The chassis 14 is disposed in a rack structure or housing 16 and is mounted thereto via mounting brackets 18. The servers 12 are configured to receive a variety of modular components, such as hard drives, fans, and power supplies, to upgrade or service the servers 12. As will be appreciated, other components disposed in the rack structure 16 may include additional computer servers, operator interfaces, etc. The rack structure 16 may have any number and configuration of rack mount receptacles having supports, such as manual or automatic rail mechanisms that support the servers 12, the chassis 14, or various other components. The exemplary servers 12 may be any size or form factor of rack-mountable servers and the disclosed embodiments are generally applicable to multiple server sizes and form factors, such as 1U, 2U, half-height blade servers, full height blade servers, etc.

The server 12 may include a number of configurations to provide various functions in the system 10. Internally, the server 12 may include a system board, hard disk drives, volatile or non-volatile memory devices, processors, controllers, interfaces, and expansion cards. Thus, the servers 12 provide processing and computational services and capabilities in a high density arrangement in the rack structure 16. Interface signals may include data transmitted from a user on a system network, or data transmitted between servers 12. Additional functionality may be added to the servers through the addition or replacement of expansion cards, processes, memory devices, etc.

For the server 12 to perform these tasks within the rack mount system 10, interface signals and power may be delivered to the server 12. Power may include a 12V power provided to the server 12 from an exemplary modular power supply 20 located in the chassis 14 of the servers 12 or rack structure 16, for example. As discussed herein, the design, size and form factor of the power supply 20 is standardized to enable the power supply 20 to be used with any of the servers 12 that may be installed in the rack mount system 10, standalone servers, or any other type of server. Further, regardless of the type of server 12, the power supply 20 may be used with a variety of input voltages and output requirements.

Thus, for example, each rack mount server 12 may have one or more than one power supply/power supplies 20 placed into a standardized receptacle in the chassis 20. Further, the power supply 20, as will be described below, may include features to ensure easy and secure installation and removal from the chassis 14. In one embodiment, the power supplies 20 may slidingly mount into or out of the receptacle in the chassis 20 and there may be more than one power supply 20 installation for each server 12. In other embodiments, the power supply 20 may be installed into a standard receptacle in the rack structure 16. Alternatively, in such an embodiment, the ratio of power supplies 20 to servers 12 may vary depending on the requirements of the servers 12 and the desired redundancy in the rack mount system 10. In addition, in some embodiments, more than one power supply 20 may be added for each server 12 to increase power provided to the server 12.

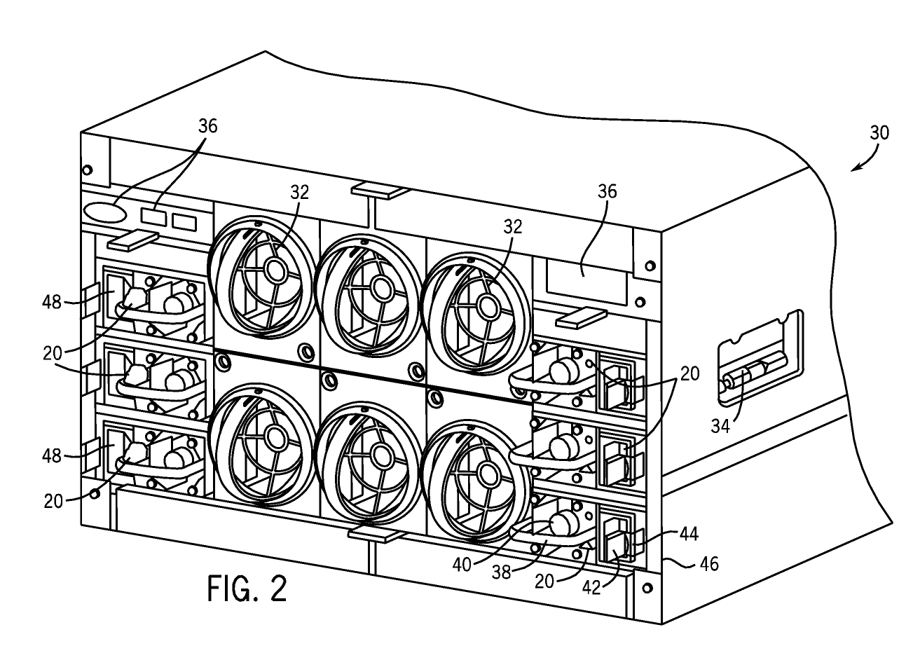

Turning now to FIG. 2, a perspective view of a blade server enclosure 30 with multiple modular power supplies 20 is shown in accordance with an embodiment of the present invention. The enclosure 30 may house multiple blade servers, including half-height and full-height blade servers. For example, in one embodiment, the enclosure 30 may house up to 8 half-height blade servers or 4 full-height blade servers. Each enclosure 30 may be expanded through the addition of blade servers, and multiple enclosures may be used to create a blade server farm to increase processing and computational power. The enclosure 30 may include other components, such as fans 32, recessed handles 34, and various connectors 36, such as for connections to a network, I/O devices, or displays.

As discussed above with regard to the rack mount servers, the blade servers may include a system board, hard disk drives, volatile or non-volatile memory devices, processors, controllers, interfaces, and expansion cards. In some embodiments, the blade servers may omit or relocate outside of the server any number of components to reduce the size and form factor of the blade server. The enclosure 30 is designed to provide the combined processing and computational power of all servers housed in the enclosure 30. Even though the configuration, size, and/or form factor of the blade servers in the server enclosure 30 may be different than the rack mount system 10 described above, the modular power supplies 20 fit into the chassis of each server and/or enclosure.

Each power supply 20 may connect to one or more servers using an output connector, as will be described further below. As seen in the FIG. 2 the front of each power supply 20 includes a handle 38, a fan 40 (located inside the power supply), button 42 and latch 44. The handle 38 provides a safe and secure location to grab for easy installation and removal of each power supply 20. The fan 40 operates to create or add air flow through or around the power supply 20, and may be a fixed-speed or variable-speed fan. The fan 40 may operate constantly or as needed depending on parameters such as interior temperature of the server, processor temperature, power-saving settings, etc.

The button 42 and latch 44 work in conjunction to secure the power supply to the enclosure 30 and to provide for easy installation and removal of the power supply 20. In one embodiment, the power supply 20 may slidingly mount into the receptacle in the enclosure 30, and thus may be installed or removed by pushing or pulling the power supply 20 via the handle 38. When the power supply is installed into the enclosure 30, the latch 44 may engage the sheet metal 46 of the enclosure 30 or may engage a receptacle cut into the sheet metal 46 of the enclosure 30. The engagement of the latch 44 with the sheet metal 46 of the enclosure 30 aids to block inadvertent or accidental removal of the power supply 20. During installation or removal of the power supply 20, a technician may disengage the latch 44 from the sheet metal 46 of the enclosure 30 by pressing the button 42, thus slightly moving the latch 44 towards the handle 38 of the power supply 20. After disengaging the latch 44, the power supply 20 is free to slide in or out of the receptacle in the enclosure 30.

Each power supply 20 includes an input connecter 48 used to connect the power supply 20 to the source of power, such as an electrical outlet of a power grid The connector 48 may connect directly to such an electrical outlet or may connect to a power strip in the enclosure, a surge protector, a UPS, etc. As will be described further below, the connecter 48 may be an International Electrotechnical Commission (IEC) appliance connector. Further, the input connector 48 may be chosen to be compatible with any input power signal, such as AC or DC power and/or different input voltages. For example, the input connector 48 may accept 60/50 Hz AC, 400 Hz AC, −48V/+48V DC, and 400V DC.

In this embodiment, each power supply 20 may be capable of outputting up to 1200 W. If more than 1200 W is needed, then multiple power supplies may be used in parallel, thus complementing the scalability of the enclosure 30. Further, to ensure redundancy and/or ensure backup power, up to six power supplies may be used in the enclosure. Any number or configuration of power supplies may be used, such as a 1, 1+1, 4+1, etc. For example, in 1 configuration, one power supply provides power for the enclosure 30. In a 1+1 configuration, both power supplies provide power for the enclosure. This configuration may be referred to as “Redundant” mode. Each power supply may deliver approximately 50% of the load. If one power supply fails one any reason, the other power supply picks up the load from the other power supply and delivers full load. The failed power supply can be removed without disturbing the other power supply or the operating server. In a 4+1 configuration, five power supplies provide power for the enclosure 30. In this 4+1 configuration, each power supply delivers approximately 20% of the load. If one power supply fails for any reason, the other power supply picks up the load from the other power supply and delivers full load. Again, the failed power supply can be removed without disturbing either the other power supplies or the operating servers in an enclosure. In other embodiments the power supply may output at least 1400 W, 1600 W, 1800 W, or any other output level.

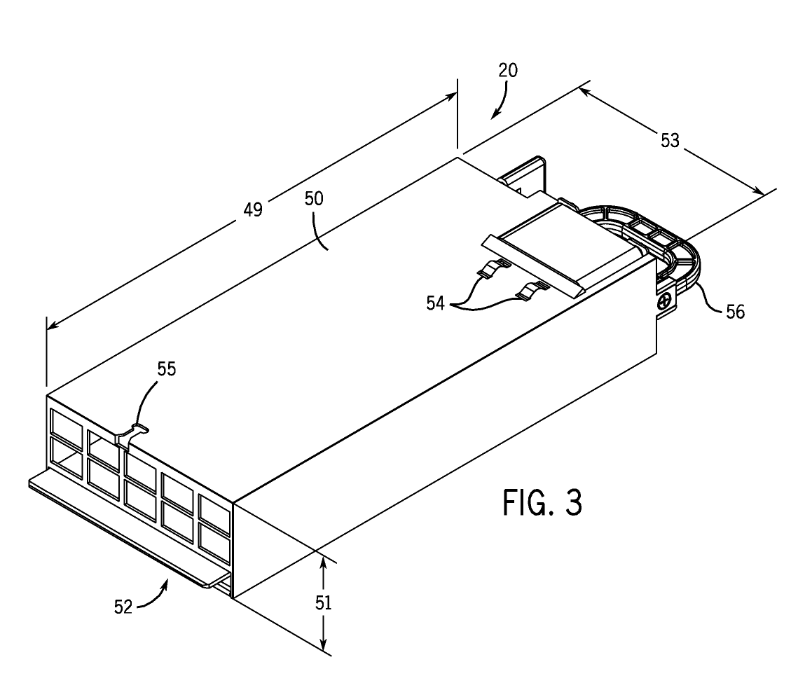

FIG. 3 depicts a rear perspective view of a modular power supply 20 having a chassis 50 in accordance with an embodiment of the present invention. In one embodiment, the chassis 50 may be formed from sheet metal, while in other embodiments the chassis may be formed from plastic or any other suitable material. The power supply 20 has an output connector 52 such as a card connector, as will be described further below. The illustrated card connector 52 is a card-edge extension of a printed circuit board (PCB) internal to the power supply. The card connector 52 is configured to blind mate with a receptacle inside a server. Thus, the card connector 52 is a standard connector (e.g., standard size, number of connection pins, etc.) disposed in a standard position (e.g., standard distance from sides of chassis 50) to facilitate uniformity across platforms, thereby enabling the modular power supply 20 to blind made with a variety of different servers. In other embodiments, the output connector 52 may be any other suitable connector, such as a plug, socket, etc.

The power supply 20 also includes retaining clips 54 and a notch 55 (e.g., key-hole slot) on the top of the power supply. The notch 55 may engage a protrusion (e.g., a boss member) on the chassis of the server in which the power supply is installed, and the retaining clips 54 may engage one or more receptacles on the chassis of the server. The engagement of the retaining clips 54 and the notch 55 may block inadvertent or accidental insertion of the power supply 20 in the wrong direction.

The power supply 20 also includes a handle 56 protruding from the front of the power supply 20. As described above, the handle 56 can be used for installation or removal of the power supply 20, and provides a safe and secure location for a technician to grab the power supply 20. The handle 56 may be formed from plastic, metal, or other suitable material, and may be formed as an extension of the chassis 50 of the power supply 20 or formed separately and coupled to the power supply 20.

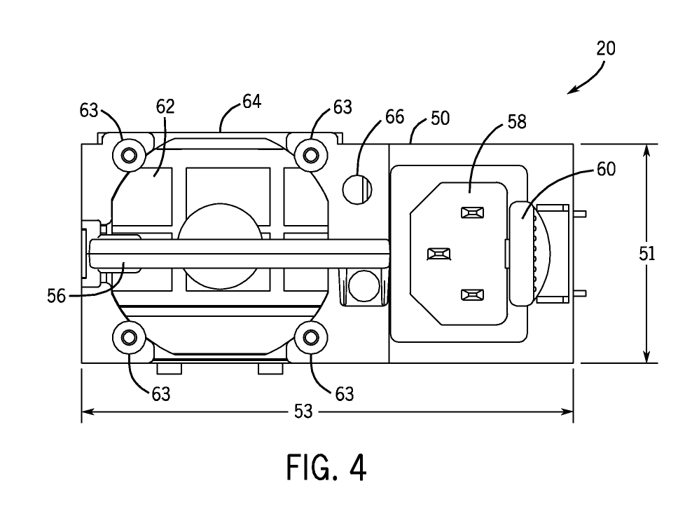

FIG. 4 depicts a front view of the modular power supply 20 in accordance with an embodiment of the present invention. As can be more clearly seen in FIG. 4, the power supply 20 includes the handle 56, an input connector 58, and a latch 60. The power supply 20 also includes a fan opening 62, isolator 64, and an LED opening 66. As discussed above in FIG. 2, the latch 60 may be used to facilitate mounting of the power supply 20 within a receptacle in various different servers, such as blade servers, rack mount servers, and so forth.

A fan may be coupled to the power supply 20 to move air in or out of the power supply 20 and through a fan opening 62. The fan may be secured to an isolator 64 (e.g., an insulative frame or duct), such as through fan holes 63, so as to be isolated from the chassis of the power supply 20. The isolator 64 may extend over the top and/or bottom of the power supply 20, and may be coupled to the chassis 50 via screws or any other fastener. Any air gaps between the fan, the isolator 64, and the chassis 50 of the power supply 20 may be filled with insulating material, such as compressed foam, plastic, rubber, etc. An opening 66 provides an opening to allow view of a light emitting diode (LED) located on the power supply 20. The LED may be a status LED used to indicate the status of the power supply 20, with different colors corresponding with a different status. For example, a green color may indicate that the power supply is “ON”, an orange color may indicate a malfunction with the power supply 20, and so on.

The input connector 58 accepts power input from a power source, and, as described above, the power supply 20 and input connector 58 may be configured to accept different types of AC or DC power, and/or different input voltages. The input connector 58 may accept an input voltage from about 90V to about 264V AC at 56 Hz, 60 Hz, or 400 Hz, or may accept, −48V/+48V or 400V DC. In the embodiment shown, the input connector 58 may be an IEC320 C-13/14 AC input connector such as the plugs and sockets that are defined in the IECT 60320 specification. According to the IEC naming convention, the input connector on the power supply 20 is a C-14 socket, and the plug that connects to the C-14 socket is a C-13 plug. The C-13/14 connector used in the embodiment is rated for 10 RMS Amps. In other embodiments, the input connector 58 may be another IEC connector, or may be any other type of suitable connector. However, in certain embodiments, this standard connector may be used to ensure uniformity of the power supply 20 across a wide range of different servers.

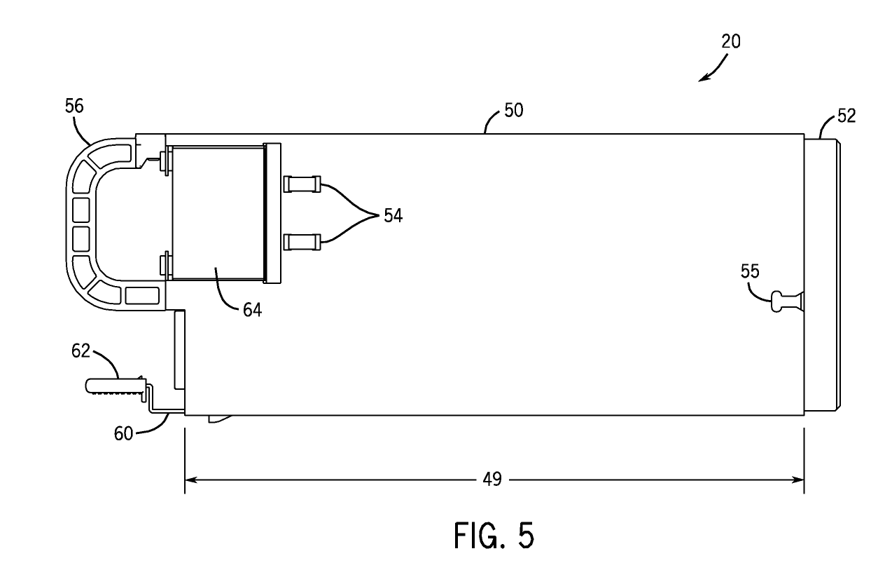

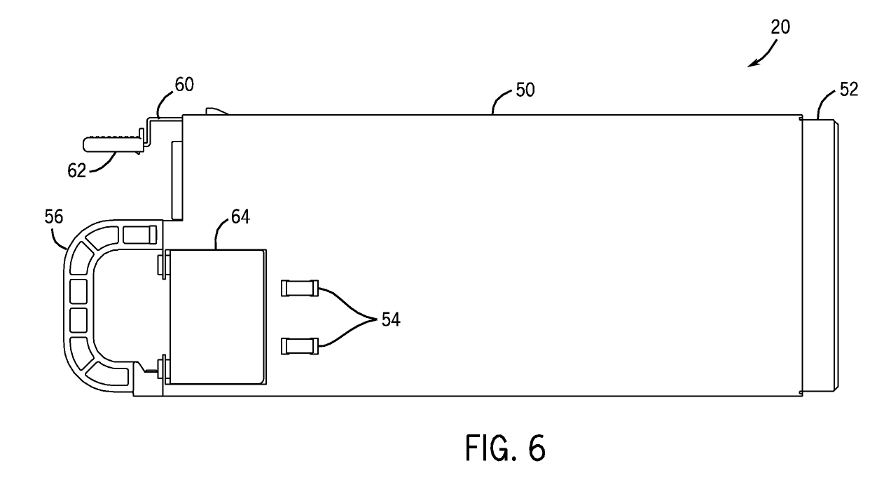

FIGS. 5 and 6 show top and bottom views respectively of the power supply 20 in accordance with an embodiment of the present invention. The top view illustrates the handle 56, the retaining clips 54, the notch 55, the isolator 64, and the output connector 52. As discussed above, the retaining clips 54 may engage receptacles on the chassis of a server, and the notch 55 (e.g., key-hole slot) may engage a protrusion (e.g., a boss member having a mushroom shaped head) on the chassis of the server to secure the power supply 20 when installed. The latch 60, shown with button 62, may also engage a receptacle or protrusion on the chassis of a server to block inadvertent or accidental removal of the power supply 20. Further, the latch 60 and button 62 may provide disengagement functionality, such that when the button 62 is pressed, movement of the latch 60 disengages the chassis of the power supply 20 from the server, as described above.

In the illustrated embodiment of FIGS. 3-6, the power supply 20 has a standard form factor with a standard length, width, and height of the chassis 50. Specifically, a length 49 of the chassis 50 of the power supply may be about 7.5±0.2 inches, a height 51 of the chassis 50 may be about 1.515±0.016 inches, and a width 53 of the chassis 50 may be about 3.4±0.016 inches. The handle 56 may extend about 1.436 inches from the back of the chassis 50 of the power supply 20. The input connector 58 may extend 0.435±0.016 from the front of the chassis 50. The width of the input connector 58 may be 3.287±0.006 inches.

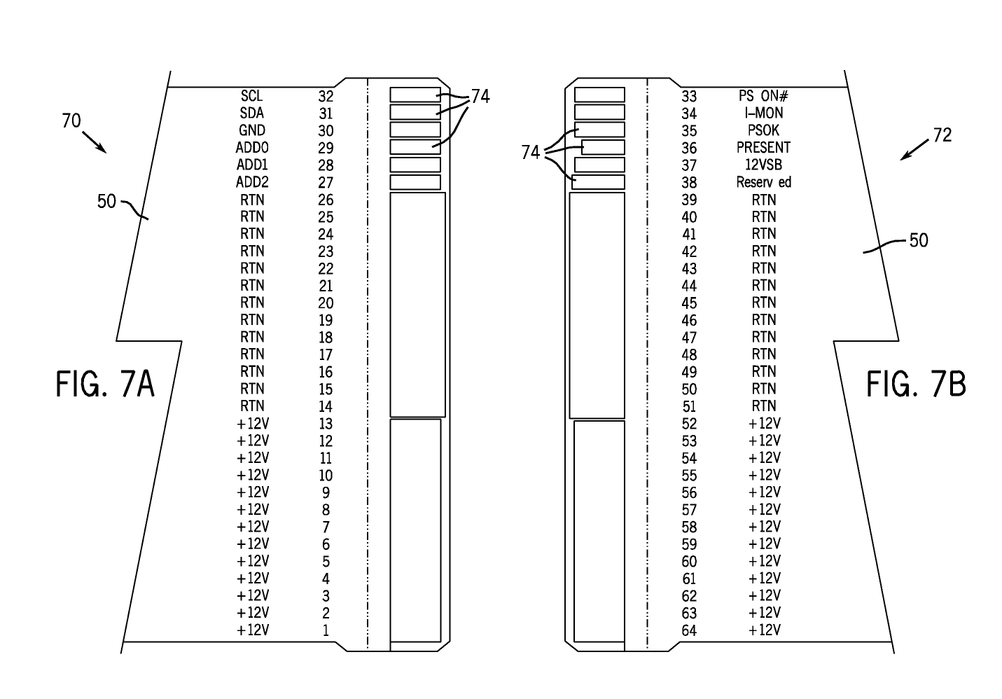

FIGS. 7A and 7B depict the top 70 and bottom 72 of an embodiment of the card-edge output connector 52 of the modular power supply 20 in accordance with an embodiment of the present invention. As described above, in this embodiment, the PCB of the power supply 20 extends beyond the power supply chassis 50 and forms the card-edge finger connections 74. The card-edge fingers 74 are numbered as shown in the figure, with 32 fingers on each side for a total of 64 fingers. In one embodiment, the mating connecters may be Tyco connectors having part numbers 1761469 (vertical) and 1761468 (right angle), manufactured by Tyco Electronics Corporation, 1050, Westlakes Drive, Berwyn, Pa. In another embodiment, the connectors may be FCI connectors having part numbers 10046971-001 LF and 10053363-200LF, manufactured by FCI USA Inc., 825 Old Trail Road, Etters, Pa.

In one embodiment, the fingers 74 may be gold-plated contact fingers, and may include a minimum of 30 micro-inches of gold over a minimum of 100 micro-inches of nickel, and free of contaminants such as solder flux, solder, and voids or defects in the plating. In one embodiment, the output connector 70 may deliver +12V isolated output voltage to a server. Each finger or pin number of the output connector may have a different function, as illustrated below in Table 1:

TABLE 1

| PIN # | FUNCTION | DESCRIPTION |
|---|---|---|
| 14-26, 39-51 | RTN | Power and Standby |
| | | Return |
| 1-13, 52-64 | +12 V | +12 V Output |
| 37 | 12VSB | +12 V Standby Output |
| 38 | Interrupt | Firmware Interrupt |
| 36 | PRESENT | Power Supply Present |
| | | Signal (shortest pin) |
| 35 | PSOK | AC input OK and +12 V |
| | | Output OK |
| 34 | I-MON | 12 V load current monitor |
| 33 | PSON# | Power Supply on/off |
| | | control signal |
| 32 | SCL | Clock |
| 31 | SDA | Data |
| 30 | GND | 12C Signal Ground |
| 29 | ADD0 | Address 0 |
| 28 | ADD1 | Address 1 |
| 27 | ADD2 | Address 2 |

While the present description has focused on a modular power supply having one input connector and one output connector, other embodiments or configurations are also envisaged. For instance, in one embodiment, the power supply 20 may have multiple input and output connectors to facilitate connection to a plurality of input connections or output connections. Further, while the embodiments described above include only one fan, in other embodiments multiple fans or passive cooling devices, such as heat sinks, may be included in the power supply 20.

What is claimed is:

1. A system comprising:
a server power supply comprising a modular chassis having dimensions standardized across a plurality of different servers, wherein the dimensions are configured to fit the modular chassis uniformly within receptacles of the plurality of different servers.

2. This system of claim 1, wherein the dimensions comprise a width of about 3.4 inches and a height of about 1.515 inches.

3. The system of claim 1, wherein the dimensions comprise a length of about 7.5 inches.

4. The system of claim 1, wherein the modular chassis is configured to slidingly mount within receptacles of the plurality of different servers.

5. The system of claim 1, wherein the server power supply comprises a card-edge connector.

6. The system of claim 5, wherein the card-edge connector extends from a system board of the server power supply and comprises 64 pins.

7. The system of claim 1, wherein the server power supply comprises an input connector, wherein the input connector comprises an IEC 320 C-14 connector.

8. The system of claim 1, wherein the server power supply comprises a handle at an end of the modular chassis.

9. The system of claim 1, comprising a server having the server power supply disposed therein.

10. The system of claim 1, comprising a family of server power supplies, wherein each of the family of server power supplies comprises a modular chassis having the same dimensions.

11. A system, comprising:
a server configured to receive a server power supply having dimensions standardized across a plurality of different servers including the server, wherein the dimensions are configured to fit the power supply uniformly within receptacles of the plurality of different servers including the server.

12. This system of claim 11, wherein the dimensions comprise a width of about 3.4 inches and a height of about 1.515 inches.

13. The system of claim 11, wherein the dimensions comprise a length of about 7.5 inches.

14. The system of claim 11, wherein the server comprises a receptacle having substantially the same dimensions configured to slidingly receive and support the server power supply.

15. The system of claim 11, wherein the server power supply comprises a card-edge connector.

16. The system of claim 15, wherein the card-edge connector extends from a system board of the server power supply and comprises 64 pins.

17. The system of claim 11, wherein the plurality of different servers comprise a blade server, or a rack mount server, or a combination thereof.

18. A method of manufacture, comprising:
providing a server power supply comprising a modular chassis having dimensions standardized across a plurality of different servers, wherein the dimensions are configured to fit the modular chassis uniformly within receptacles of the plurality of different servers.

19. This method of claim 18, wherein the dimensions comprise a width of about 3.4 inches and a height of about 1.515 inches.

20. The method of claim 18, wherein the dimensions comprise a length of about 7.5 inches.

21. The method of claim 18, wherein providing the server power supply comprises providing a card-edge connector on an interior end of the server power supply.

22. The method of claim 21, wherein providing the card-edge connector comprises providing 32 pins on each side of a card edge of a system board of the server power supply.

23. The method of claim 18, wherein providing the server power supply comprises providing an IEC 320 C-14 input connector on an exterior end of the server power supply.
